(19) United States
(12) Patent Application Publication
(10) Pub. No.: US 2008/0024961 A1
(43) Pub. Date: Jan. 31, 2008

(54) WEARABLE ELECTRONIC DEVICE WITH EDGE-MOUNTED BATTERY

(76) Inventors: Robert C. Anderson, Cumming, GA (US); James Pierce, Cumming, GA (US)

Correspondence Address: GARDNER GROFF GREENWALD & VILLANUEVA. PC, 2018 POWERS FERRY ROAD, SUITE 800, ATLANTA, GA, 30339, US

(21) Appl. No.: 11/774,743

(22) Filed: Jul. 9, 2007

Related U.S. Application Data
(60) Provisional application No. 60/807,871, filed on Jul. 20, 2006.

(51) Int. Cl. H05K 5/00; H05K 7/14

(52) U.S. Cl. 361/679

(57) ABSTRACT

An improved PDA-like electronic device includes a housing having a display screen on the front and a battery positioned along the edge or side of the housing, to allow the battery to be removed and replaced without requiring access to the back of the housing. The housing includes a curved back portion to conform generally to the user's body, such as the user's arm. By placing the battery along the side or edge of the housing, the battery can be accessed without removing the battery from the user's body.

### CROSS-REFERENCE TO RELATED APPLICATION

The present application is a continuation of Provisional Patent Application Ser. No. 60/807,871, filed Jul. 20, 2006, which is hereby incorporated by reference in its entirety for all purposes.

### FIELD OF THE INVENTION

The present invention relates generally to the field of portable electronic devices, such as PDA-like devices. In particular, the present invention relates to a PDA-like device adapted to be worn on the wrist.

### BACKGROUND OF THE INVENTION

Portable computers and communications devices have developed to the point that it is common to have a portable, small (often a few inches across by several inches long) device that can serve as a computer accomplishing various tasks. One example of such a portable computer is the so-called Personal Digital Assistant (PDA). These devices often are connected to a wireless network of some sort to allow the devices to send and receive messages and/or to send and receive data. However, when displaying a message or data, it is desirable to have a display screen that is as large as practical in order to make the messages and/or data easier to read.

Unfortunately, larger display screens tend to be heavier and consume precious battery life faster than smaller screens. In certain applications, it can be desirable to strap the PDA to a user's body in order to keep the device handy, to free up one's hands, and to secure it in a location where it can be used readily. Various electronic devices have been attached to a user's arm or leg to accomplish this. Inconveniently, the battery in most such devices is accessed from the back, requiring that the user take off the electronic device in order to access or service the battery.

Accordingly, it can be seen that a need yet exists for a wearable portable electronic device that allows the battery to be serviced and replaced without requiring that the wearer (user) remove the portable electronic device from his or her body. It is to the provision of such a portable electronic device that the present invention is primarily directed.

### SUMMARY OF THE INVENTION

Briefly described, in a first preferred form the present invention comprises a wearable electronic device for use by a wearer. Preferably, the device is adapted to be worn on the lower arm (wrist), but it could be adapted to be worn elsewhere. The electronic device includes a housing having a front, a back and sides. Preferably, the back of the housing is curved to be placed adjacent a portion of the wearer's arm. The electronic device further includes a display screen at the front of the housing and a battery positioned along one of the sides or edges of the housing. In this way, the battery can be removed and replaced without removing the wearable electronic device from the wearer's arm.

In one preferred form of the invention, the battery snaps into place along the side or edge of the housing and has a release button for releasing the battery from the housing. In an alternative form of the invention, the battery slides into place along the side or edge of the housing, to reach a mating position.

Advantageously, the present invention allows the battery to be removed and replaced without removing the wearable electronic device from the wearer's body. In many applications, this is a very significant advantage.

Preferably, the wearable electronic device further includes an internal main battery and the battery positioned along one of the sides or edges comprises an auxiliary battery. Optionally, the auxiliary battery can be used to recharge the main battery and to power the wearable electronic device.

In one application of the present invention, the wearable electronic device is a PDA-like device configured for receiving communications and data. Such a device can be used in a wide range of applications, such as in the delivery service industry, in military units, etc.

Defined another way, the present invention comprises an improvement to existing PDA-like electronic devices. Such devices typically include a housing having a display screen on the front and a battery compartment on the back. The improvement comprises positioning a battery along the edge or side of the housing, to allow the battery to be removed and replaced without requiring access to the back of the housing. In some situations, the housing would be worn on the body of the user and thus the back of the housing is not as accessible as the front or the sides. By placing the battery along the side or edge of the housing, the battery can be accessed without removing the device from the user's body. Optionally, the improvement can include providing a curved back portion of the housing to conform generally to the user's body, such as the user's arm.

Other advantages and benefits of the present invention will become apparent upon reading and understanding the present specification when taken in conjunction with the appended drawings.

### BRIEF DESCRIPTION OF THE DRAWINGS

FIG. 1 is a perspective view of a wearable electronic device according to a first example embodiment of the present invention.

FIG. 2 is a left side view of the wearable electronic device of FIG. 1.

FIG. 3 is a right side view of the wearable electronic device of FIG. 1.

FIG. 4 is a top view of the wearable electronic device of FIG. 1.

FIG. 5 is a bottom view of the wearable electronic device of FIG. 1.

FIG. 6 is a front view of the wearable electronic device of FIG. 1 shown with battery fully engaged.

FIG. 7 is a back view of the wearable electronic device of FIG. 1 shown with battery fully engaged.

FIG. 8 is a perspective view of the wearable electronic device of FIG. 1 shown with battery partially disengaged.

FIG. 9 is a front view of the wearable electronic device of FIG. 1 shown with battery partially disengaged.

FIG. 10 is a perspective view of a wearable electronic device according to a second example embodiment of the present invention.

FIG. 11 is a left side view of the wearable electronic device of.

FIG. 12 is a right side view of the wearable electronic device of FIG. 10.

FIG. 13 is a top view of the wearable electronic device of FIG. 10.

FIG. 14 is a bottom view of the wearable electronic device of FIG. 10.

FIG. 15 is a front view of the wearable electronic device of FIG. 10 shown with battery fully engaged.

FIG. 16 is a back view of the wearable electronic device of FIG. 10 shown with battery fully engaged.

FIG. 17 is an exploded, perspective view of the wearable electronic device of FIG. 11 shown with battery disengaged and removed.

FIG. 18 is an exploded front view of the wearable electronic device of FIG. 11 shown with battery disengaged and removed.

### DETAILED DESCRIPTION

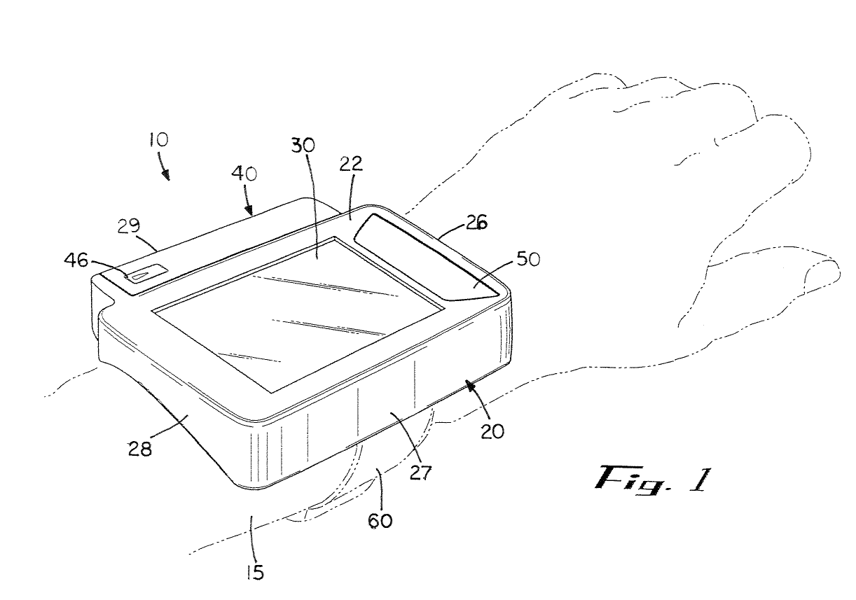

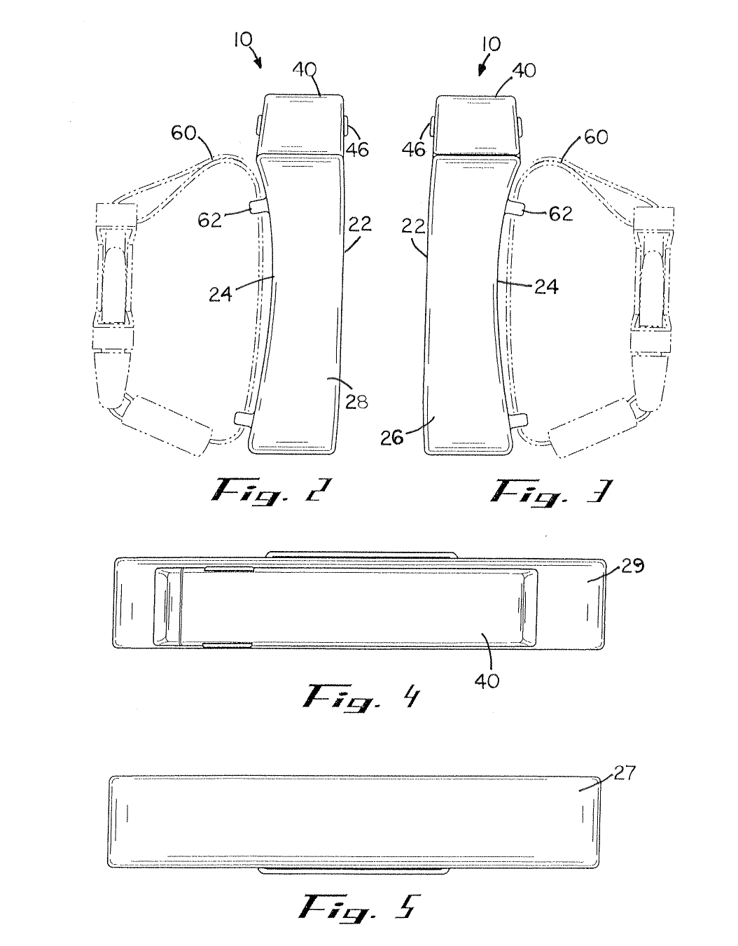

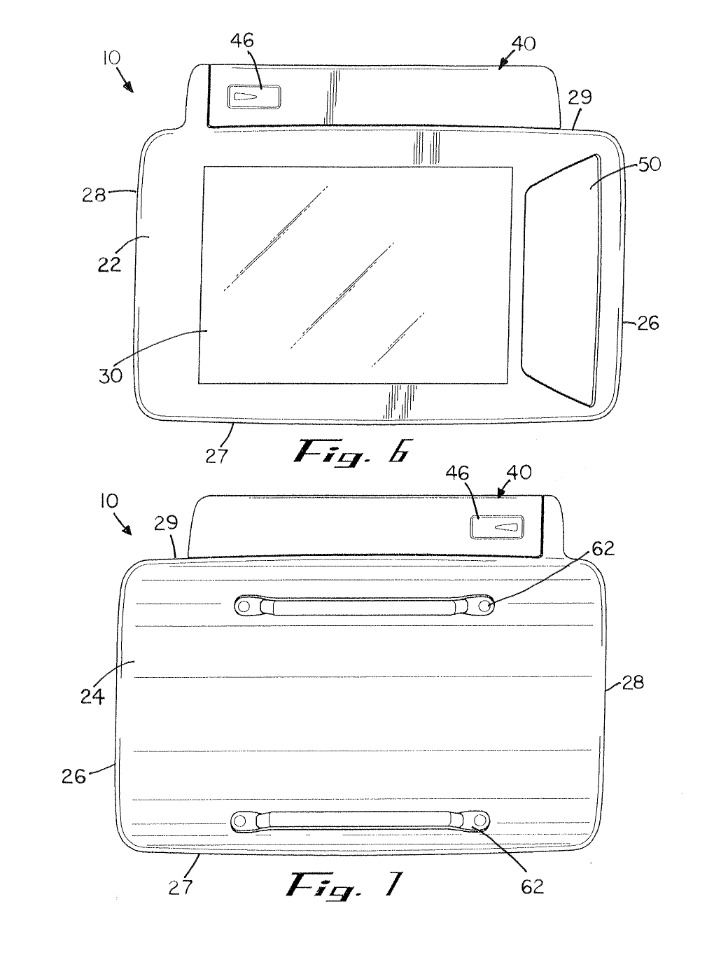

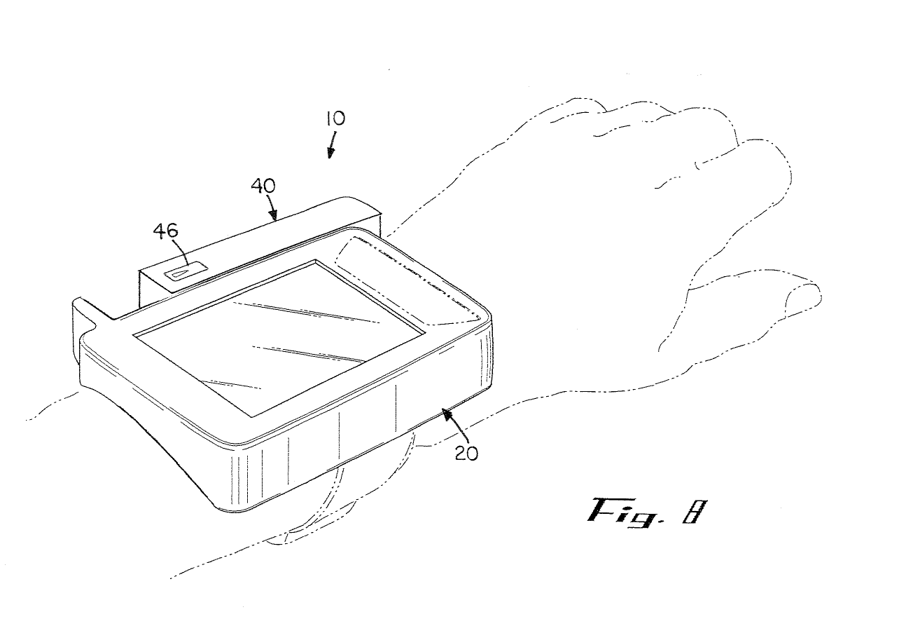

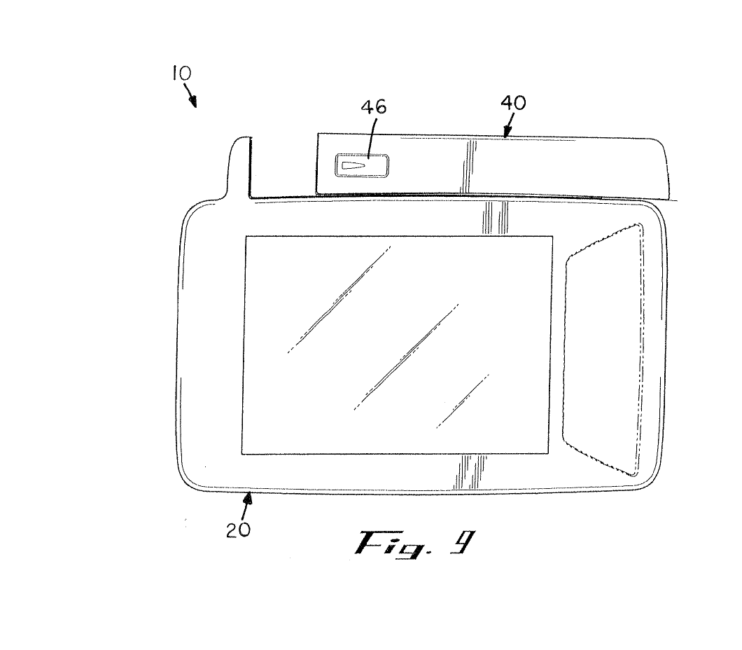

Referring now to the drawings, in which like numerals represent like elements or steps throughout the several views, FIGS. 1-9 depict a wearable electronic device 10 according to an example embodiment of the present invention. The device 10 comprises a housing 20, a display screen 30, and a battery 40. The wearable electronic device 10 of the present invention can be any number of electronic devices including, but not limited to, PDA-like devices configured to receive and transmit communications and data to or from the wearer or an external source. Such a device has many functions and uses in a wide range of applications, such as in the delivery service industry, in military units, or other applications in which a user wishes to access computer data in situations wherein the use of a traditional computer is impossible or impractical.

Generally, the housing 20 of the present invention comprises a front surface 22, a back surface 24, side surfaces 26 and 28, along with top and bottom surfaces 27 and 29 respectively. By and large, the housing 20 is formed in a rectangular shape, but can be formed in any number of shapes including, but not limited to, circular, elliptical, polygonal, etc. The housing 20 can be made from a variety of materials; however, in preferred forms, the housing can be made of lightweight materials such as polymers, rubbers, and lightweight metals.

The back surface 24 can be curved to accommodate the curvature of a wearer's arm 15 as seen in FIGS. 1-3 so that the electronic device 10 can be worn on the arm of a wearer. In a preferred form of the example embodiment, the back surface 24 has a generally cylindrical concave surface such that the radius of curvature remains constant over the length L of the housing 20. In this form, the housing can easily conform to a wearer's left or right arm. In still another preferred form, the back surface 24 of the present invention can be frustoconical, so that the radius of curvature of the back surface diminishes across the length L of the housing 20. This tapered curvature matches the tapered aspect of the human forearm (bigger at the elbow and smaller at the wrist). A tapered curved back would then fit one way, not the other, on a user's forearm. For use on either arm, left and right models could be provided. Alternatively, the housing could have two portions, a flat box-like portion and a tapered, curved mount. The tapered curved mount could be repositionable relative to the flat box-like portion so that in one orientation the device could be worn on the left wrist. To wear this alternative device on the right arm, the flat, box-like portion can be reoriented so that the curved mount is oriented in the opposite direction. In such forms, a user can rotate the housing 20 to accommodate either a left-handed or right-handed orientation as desired by the wearer.

The display screen 30 is positioned at the front surface 22 of the housing 20 as depicted in FIG. 1. The screen 30 can provide data and output to the wearer and/or allow a wearer to provide input to the electronic device 10. Additionally, at least one input button or pad 50 can be provided on the front surface 22 of the housing 20 to allow wearer interaction with the electronic device 10. In alternate forms of the present invention, multiple buttons or pads 50 may be provided for interaction with the electronic device 10 for the convenience of the wearer.

The electronic device 10 can utilize a strap or band 60 to hold the device in place on a wearer's arm as best seen in FIGS. 1-3. In a preferred form, the strap 60 can be looped through two connectors 62 extending from the back surface 24 of the housing 20. In alternative forms, the strap 60 can be integrated within the housing 20 of the electronic device 10. In still other forms, the electronic device 10 can fit within a pouch strapped to the wearer's arm. A single strap can be used or multiple straps. In the case of a single strap, it is preferred that the strap be fairly wide. Indeed, the strap could even be as wide as the device is long (or more).

The battery 40 of the electronic device 10 is positioned along one of the sides 26-29 of the housing 20, as best seen in FIGS. 1 and 6-7. In such a configuration, the battery can be removed and replaced without removing the wearable electronic device 10 from the wearer's arm. This configuration is an improvement over prior PDA-like electronic devices which typically feature a display screen on the front of the device and a battery compartment on the back. In one form of the present invention, the battery 40 can slide into releasable engagement with the housing 20 of the electronic device 10 as seen in FIGS. 8-9. The battery 40 connects to the housing 20 by sliding on rails positioned along the length of the housing, similar to a sliding dovetail joint, and can be fastened to the housing with a clip or snap (not shown). When the battery 40 is fully engaged with the housing 20, the terminals of the battery are adjacent corresponding terminals within the housing for communicating electrical power. The battery 40 can provide the main power to operate the electronic device 10, or the battery can serve as an auxiliary power source designed primarily to recharge an internal battery within the electronic device and/or to serve as a backup. To disconnect the battery 40 from engagement with the housing 20, the wearer can depress at least one release button 46 to disengage the clip or snap, and thereby allowing the wearer to slide the battery away from the housing. Advantageously, in this manner the battery can be removed and replaced with the device still on the user's arm. In alternate forms of the present invention, the battery 40 can directly snap into place without the use of rails as presented in the following embodiment.

The rails securely position the battery relative to the housing in two different directions. Firstly, the rails ensure a consistent front-to-back position of the battery relative to the housing. In this regard, the rails ensure that the battery is (and remains) in the plane of the housing. Secondly, the rails ensure that the battery is held snugly against the side or edge of the housing. To accomplish these dual purposes, the dual rails are each angled, but in opposite directions. Alternatively, instead of dual, outwardly splayed rails, a single, solid dovetail-shaped rail could be provided. Also, dual rails having right angle (L-shaped) cross-sections could be used. Those skilled in the art will recognize that other guide rail configurations can be employed, as desired.

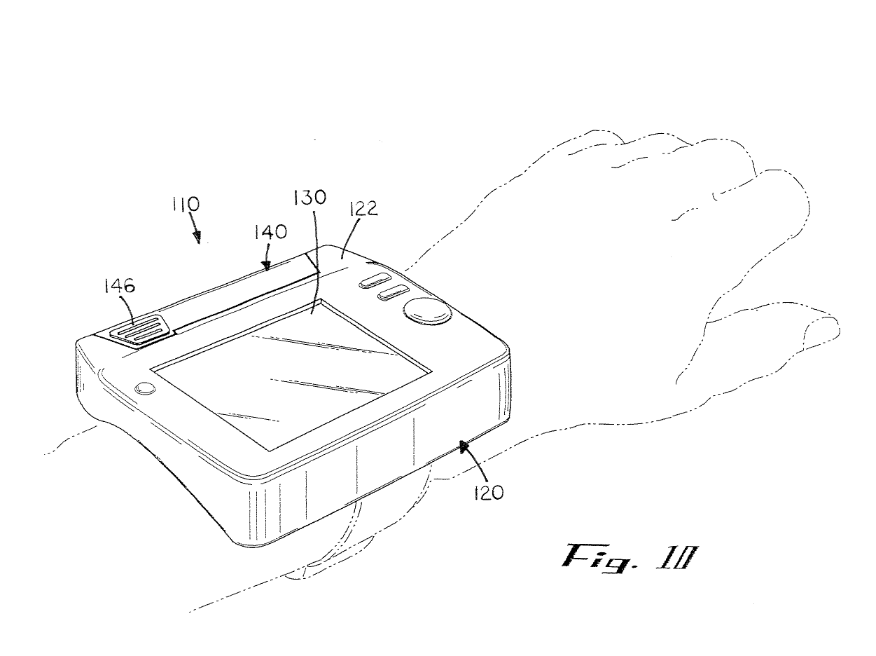

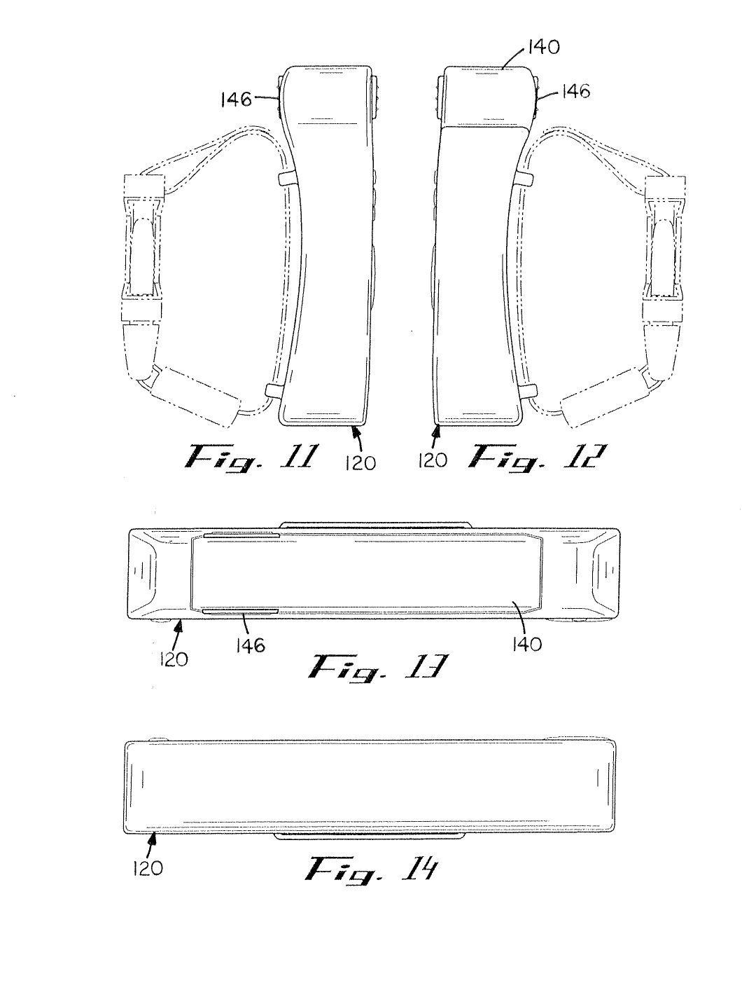

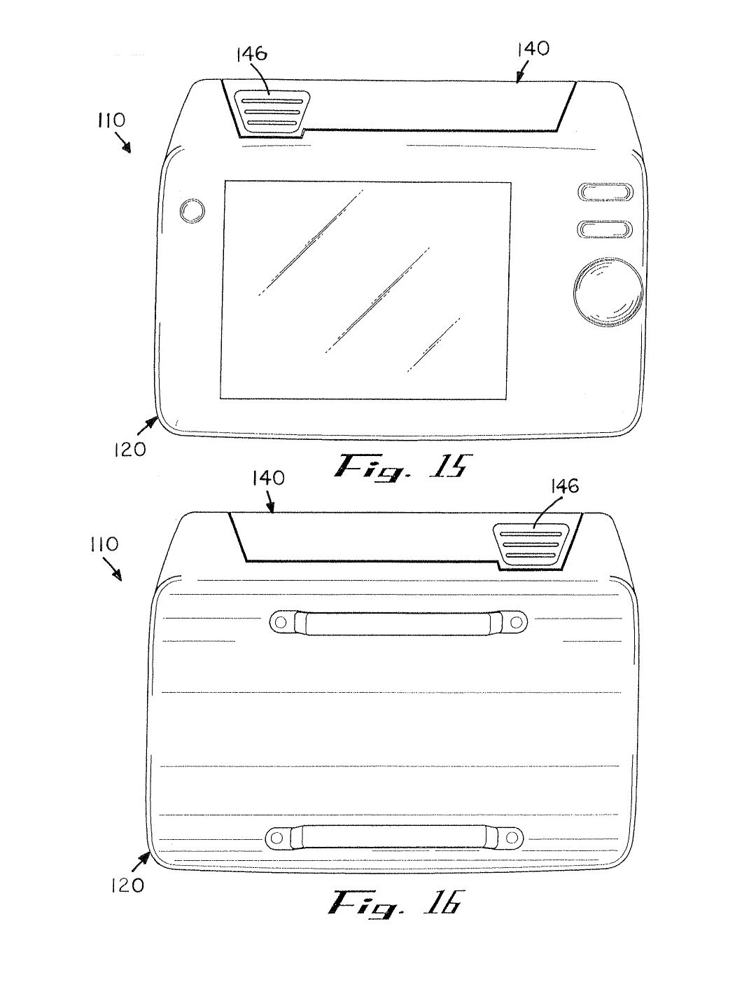

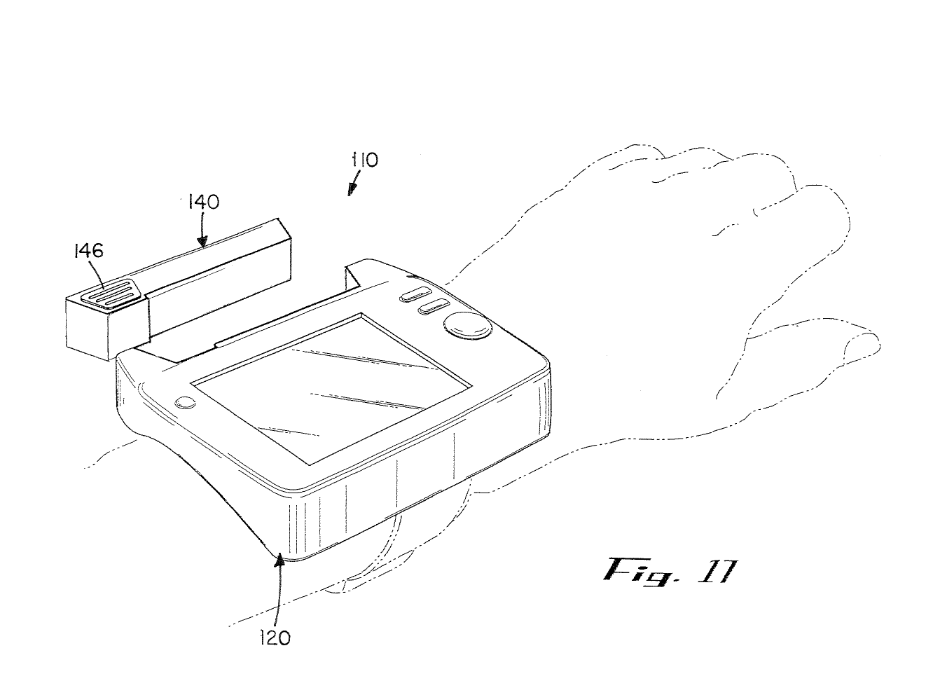

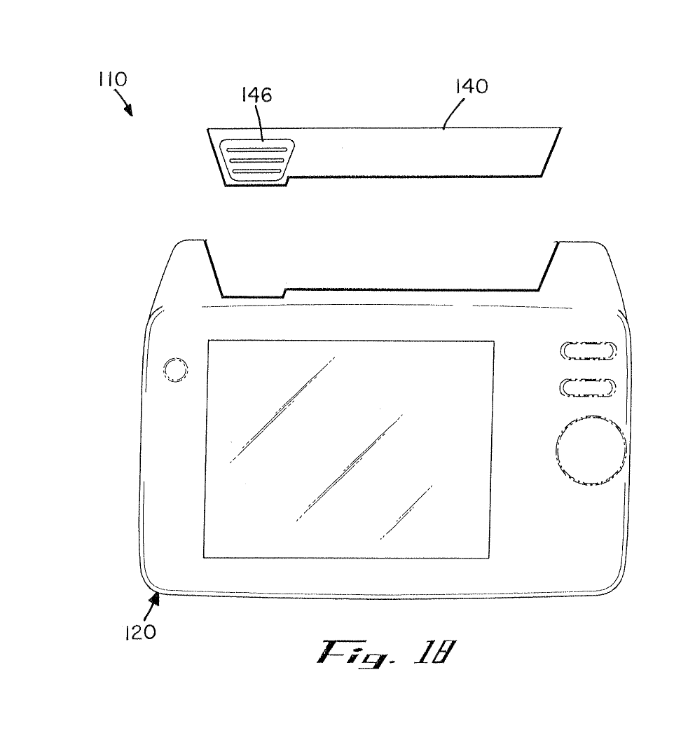

FIGS. 10-18 show a wearable electronic device 110 according to a similar second example embodiment of the present invention comprising a housing 120, a display screen 130 and a battery 140. In this embodiment, however, the battery 140 snaps into engagement with the housing 120, rather than sliding into engagement as demonstrated in the prior embodiment. In this regard, the housing 120 defines a shallow, wedge-shaped recess along one side or edge and the battery 140 has a shape that corresponds to the shallow wedge-shaped recess. In this way, the battery is nestably received in the edge or side of the housing 120 in a mating fashion.

The housing 120 is provided with a tab or striker for securing the battery 140 to the housing. The battery 140 has a corresponding striker recess to engage the striker. Preferably, the battery 140 is provided with at least one release button 146 to release the battery 140 from the housing 120. Optionally, the battery can be provided with a pair of release buttons at this end of battery, one on an upper face (as shown) and one on the lower face. In this configuration, a user can grasp the pair of release buttons between his or her thumb and forefinger. Additionally, the battery 140 can have a toe corresponding to a small recess or pocket in the housing to further secure the battery to the housing. In this way, the toe end of the battery is prevented from coming loose, except when the opposite end (the release button end) is loosed first.

In operation, a wearer needing to change the battery 140 of the electronic device 110 can depress the release button 146 and remove the battery from the housing 120 without having to remove the device from the wearer's arm. The wearer can then insert a new battery 140 by inserting the toe of the battery into the corresponding recess within the housing 120 and then rotating the battery 140 into the wedge-shaped opening, moving the striker recess over the striker to secure the new battery to the housing. In a preferred form of this embodiment, electrical terminals or contacts are located on the bottom of the battery 140 in order to mate with corresponding terminals within the housing 120 for providing the electronic device 110 with electrical power. In alternative forms, the terminals may be located in other locations on the battery 140 having a surface adjacent to a corresponding surface on the housing 120.

Whereas this invention has been described in detail with particular reference to exemplary embodiments and variations thereof, it will be understood that other variations and modifications can be made within the scope and spirit of the invention, as described herein before and as defined in the appended claims.

1. A wearable electronic device for use by a wearer and comprising:
a housing having a front, a back and sides, with the back being curved to be placed adjacent a portion of the wearer's arm;
a display screen at the front of the housing; and
a battery positioned along one of the sides, wherein the battery can be removed and replaced without removing the wearable electronic device from the wearer's arm.

2. A wearable electronic device as claimed in claim 1 wherein the wearable electronic device is generally rectangular with two longer sides and two shorter sides.

3. A wearable electronic device as claimed in claim 2 wherein the battery is positioned along one of the longer sides.

4. A wearable electronic device as claimed in claim 3 wherein the battery snaps into place and has a release button for releasing the battery from the housing.

5. A wearable electronic device as claimed in claim 3 wherein the battery slides along the length of the longer side to reach a mating position.

6. A wearable electronic device as claimed in claim 5 wherein the battery is slidably secured along the length of the longer side with one or more rails.

7. A wearable electronic device as claimed in claim 1 wherein the wearable electronic device is a PDA-like device configured for receiving communications and data.

8. A wearable electronic device for use by a wearer and comprising:
a housing having a front, a back and sides, with the back being adapted to be placed adjacent a portion of the wearer's body;
a display screen positioned at the front of the housing; and
a battery positioned along one of the sides.

9. A wearable electronic device as claimed in claim 8 wherein the battery can be removed and replaced without removing the wearable electronic device from the wearer's body.

10. A wearable electronic device as claimed in claim 8 wherein the wearable electronic device is adapted to be worn on the arm and is generally rectangular with two longer sides and two shorter sides.

11. A wearable electronic device as claimed in claim 10 wherein the battery is positioned along one of the longer sides.

12. A wearable electronic device as claimed in claim 11 wherein the battery snaps into place and has a release button for releasing the battery from the housing.

13. A wearable electronic device as claimed in claim 11 wherein the battery slides along the length of the longer side to reach a mating position.

14. A wearable electronic device as claimed in claim 13 wherein the battery is slidably secured along the length of the longer side with one or more rails.

15. A wearable electronic device as claimed in claim 8 further comprising an internal main battery and wherein the battery positioned along one of the sides comprises an auxiliary battery.

16. A wearable electronic device as claimed in claim 15 wherein the auxiliary battery is used to recharge the main battery and to power the wearable electronic device.

17. A wearable electronic device as claimed in claim 8 wherein the wearable electronic device is a PDA-like device configured for receiving communications and data.

18. A wearable electronic device as claimed in claim 14 wherein the one or more rails comprise a sliding joint between the housing and the battery.

19. A wearable electronic device as claimed in claim 8 wherein the back of the housing is smoothly contoured to fit a portion of the wearer's body.

20. In a PDA-like electronic devices of the type including a housing having a display screen on the front, the improvement therein comprising:
positioning a battery along the edge or side of the housing, to allow the battery to be removed and replaced without requiring access to the back of the housing.

21. The improvement as claimed in claim 20 further wherein the housing comprises a curved back portion to conform generally to the user's arm.
